(19) United States
(12) Patent Application Publication
(10) Pub. No.: US 2019/0305105 A1
(43) Pub. Date: Oct. 3, 2019

(54) GATE SKIRT OXIDATION FOR IMPROVED FINFET PERFORMANCE AND METHOD FOR PRODUCING THE SAME

(71) Applicant: GLOBALFOUNDRIES Inc., Grand Cayman (KY)

(72) Inventors: Qun GAO, Clifton Park, NY (US); Christopher NASSAR, Ballston Spa, NY (US); Sugirtha KRISHNAMURTHY, Ballston Spa, NY (US); Domingo Antonio FERRER LUPPI, Clifton Park, NY (US); John SPORRE, Cohoes, NY (US); Shahab SIDDIQUI, Clifton Park, NY (US); Beth BAUMERT, Ballston Lake, NY (US); Abu ZAINUDDIN, Ballston Lake, NY (US); Jinping LIU, Ballston Lake, NY (US); Tae Jeong LEE, Clifton Park, NY (US); Luigi PANTISANO, Saratoga Springs, NY (US); Heather LAZAR, Saratoga Springs, NY (US); Hui ZANG, Guilderland, NY (US)

(21) Appl. No.: 15/943,272

(22) Filed: Apr. 2, 2018

(51) Int. Cl. H01L 29/66; H01L 29/78; H01L 29/49; H01L 29/423

(52) U.S. Cl. CPC H01L 29/6656; H01L 29/42364; H01L 29/49; H01L 29/785

(57) ABSTRACT

A method for controlling the gate length within a FinFET device to increase power performance and the resulting device are provided. Embodiments include forming a vertical gate to extend over a plurality of fins; depositing a respective oxide layer over each of a plurality of skirt regions formed at respective points of intersection of the vertical gate with the plurality of fins; and oxidizing each oxide layer to form a plurality of oxidized gate skirts.

### TECHNICAL FIELD

The present disclosure relates to fin field effect transistor (FinFET) devices and fabrication thereof. In particular, the present disclosure relates to oxidized gate skirts for increased FinFET performance.

### BACKGROUND

Transistors have been continuously scaled down in size to increase performance and reduce power consumption. This has led to the advent of more efficient, scalable electronic devices and increased user experiences. However, downsizing has also increased the complexity of device manufacturing. One challenge faced by manufacturers of FinFETs and other multi-gate devices is maximizing power performance. Unfortunately, device scaling and fabrication process may introduce defects that minimize alternating current (AC) performance. For example, the length of the metal gates that extend perpendicularly over the fins may be inadvertently extended during etching. The extended length of the gate results in increased gate capacitance, which limits AC performance.

A need therefore exists for a FinFET device with a controlled gate length for increased power performance, and for a method of fabrication thereof.

### SUMMARY

An aspect of the present disclosure is a FinFET device with increased power performance.

Another aspect of the present disclosure is a method for controlling the gate length within a FinFET with a first and second oxidized portion of a spacer and low-dielectric portion of the spacer formed adjacent to a gate.

Additional aspects and other features of the present disclosure will be set forth in the description which follows and in part will be apparent to those having ordinary skill in the art upon examination of the following or may be learned from the practice of the present disclosure. The advantages of the present disclosure may be realized and obtained as particularly pointed out in the appended claims.

According to the present disclosure, some technical effects may be achieved in part by a method including: forming a vertical gate to extend over a plurality of fins; depositing a respective oxide layer over each of a plurality of skirt regions formed at respective points of intersection of the vertical gate with the plurality of fins; and oxidizing each oxide layer to form a plurality of oxidized gate skirts.

Aspects of the present disclosure include forming spacers along each side of the vertical gate and adjacent to the plurality of oxidized gate skirts, wherein effective area of the spacers includes respective area of the plurality of oxidized gate skirts. Further aspects include the spacer which includes amorphous silicon (a-Si), silicon oxycarbonitride (SiOCN) or silicoboron carbonitride (SiBCN). Another aspect includes depositing the respective oxide layer by atomic layer deposition (ALD) or plasma enhanced ALD.

Additional aspects include oxidizing each oxide layer by: applying precursors to the plurality of skirt regions for reacting with each respective oxide layer, wherein the precursors include (N,N-dimethylamino)trimethylsilane, (CH3)3 SiN(CH3)2, vinyltrimethoxysilane, trivinylmethoxysilane (CH2¼CH)3 SiOCH3), tetrakis (dimethylamino) silane Si(N(CH3)2)4, tris(dimethylamino)silane (TDMAS) SiH(N(CH3)2)3, CH2¼CHSKOCH3)3, Diisopropylaminosilane (DIPAS) with oxygen plasma as a reactant and bis(ethyl-methyl-amino)silane (BEMAS) with ozone as reactant. Further aspects include the reaction occurring within a reaction chamber at a temperature of room temperature to 600° C. and each respective oxide layer is exposed to the sequence of precursors for 20 seconds to 4 hours. Additional aspects include the reaction chamber operated at a power level of 10 watts to 100 watts. Further aspects include the reaction chamber operated at an open valve pressure of 0 millitorr (mTorr) to 1 mTorr. Another aspect includes forming the oxide layer of silicon dioxide (SiO₂), silicon oxynitride (SiON) or titanium dioxide (TiO₂). Additional aspects include forming the vertical gate perpendicular to the plurality of fins, wherein the vertical gate includes a-Si, silicon germanium (SiGe) or epitaxial silicon.

Another aspect of the present disclosure is a device including: a plurality of fins formed within a substrate; a vertical gate formed to extend perpendicularly over the plurality of fins; and a plurality of oxidized gate skirts formed to fill in respective skirt regions formed at a point of intersection of the vertical gate and the plurality of fins.

Aspects of the device include spacers formed along each side of the vertical gate and adjacent to the plurality of oxidized gate skirts, wherein effective area of the spacers include respective area of the plurality of oxidized gate skirts. Another aspect includes the spacers formed of a-Si, SiOCN or SiBCN. Other aspects include a plurality of oxide layer deposited over each of the respective skirt regions. A further aspect includes the oxide layer deposited by ALD or plasma enhanced ALD. Another aspect includes the oxide layer which includes SiO₂, SiON or TiO₂. Other aspects include the vertical gate which is perpendicular to the plurality of fins, and wherein the vertical gate includes a-Si, SiGe or epitaxial silicon.

A further aspect of the present disclosure is a device including: a first and second oxidized portion of a spacer formed over a first and second skirt region of a gate; and a low-dielectric portion of the spacer formed adjacent to the gate and the first and second oxidized portion of the spacer, wherein the first and second skirt regions are formed at a respective point of intersection of the gate with a respective first and second fin.

Aspects of the present disclosure include forming the first and second oxidized portions of the spacer of SiO₂, SiON or TiO₂. Another aspect includes forming the low-dielectric portion of the spacer of a-Si, SiOCN or SiBCN.

Additional aspects and technical effects of the present disclosure will become apparent to those skilled in the art from the following detailed description wherein embodiments of the present disclosure are described simply by way of illustration of the best mode contemplated to carry out the present disclosure. As will be realized, the present disclosure is capable of other and different embodiments, and its several details are capable of modifications in various obvious respects, all without departing from the present disclosure. Accordingly, the drawings and description are to be regarded as illustrative in nature, and not as restrictive.

### BRIEF DESCRIPTION OF THE DRAWINGS

The present disclosure is illustrated by way of example, and not by way of limitation, in the figures of the accompanying drawing and in which like reference numerals refer to similar elements and in which:

FIGS. 1A and 1B schematically illustrate top-down view of a FinFET having a plurality of skirt regions, in accordance with exemplary embodiments;

FIGS. 1C and 1D schematically illustrate top-down views of a FinFET having a plurality of oxidized skirts for filling in a plurality of skirt regions, in accordance with exemplary embodiments; and

FIG. 1E schematically illustrates a three-dimensional view of a cross-section of a FinFET having a plurality of oxidized skirts for filling in a plurality of skirt regions, in accordance with an exemplary embodiment.

### DETAILED DESCRIPTION

In the following description, for the purposes of explanation, numerous specific details are set forth in order to provide a thorough understanding of exemplary embodiments. It should be apparent, however, that exemplary embodiments may be practiced without these specific details or with an equivalent arrangement. In other instances, well-known structures and devices are shown in block diagram form to avoid unnecessarily obscuring exemplary embodiments. In addition, unless otherwise indicated, all numbers expressing quantities, ratios, and numerical properties of ingredients, reaction conditions, and so forth used in the specification and claims are to be understood as being modified in all instances by the term “about.”

The present disclosure addresses and solves the problem of extended gate lengths occurring within a FinFET device, such as gate skirts. Gate skirt refers to a physical characteristic where a skirt-shaped protrusion or ledge is formed near a point of intersection (corner) of a metal gate of the device and one or more fins as opposed to a straight edged corner. When gate skirts occur, the effective length of the gate is increased, this also results in increased gate capacitance and limited AC performance.

Gate skirts are typically formed during the gate reactive ion etch (ME) process, where ion confinements on the corners result in RX holes (unwanted etching of FIN channel). Left unchecked, gate skirts skew the expected operation and/or performance of the device relative to the intended design specifications. For example, when metal is deposited over the fin to form the gate, the skirt region is also metallicized, thus increasing the effective length of the metal gate over the fin and the effective capacitance of the gate. A skewed gate length (e.g., of as little as 3% per nanometer) also penalizes AC circuit performance across the gate from source to drain.

Unfortunately, reducing gate skirts is challenging for semiconductor manufacturers, especially during polysilicon etching. Etching is required for forming and/or patterning the fins or gate to specification, including attempts to remove gate skirts. However, over etching of the gate skirt may introduce active area holes (RX holes) in the active gate or fin while under etch results in residue build-up of the etched material. Gate skirts may also cause downstream severe RX holes during subsequent fabrication, as during metal gate via execution of a replacement metal gate (RMG) procedure. Still further, downstream gate leakage reliability issues may arise from improper breakdown voltage occurring during true-single-phase-clocking fabrication.

The problems mentioned above are solved, inter alia, by forming oxidized skirts to fill in gate skirt regions of a device, in accordance with embodiments of the present disclosure. For the purpose of illustration herein, the exemplary embodiments are described with respect to a FinFET device. However, the exemplary device and method as described may apply to the fabrication and/or design of any single or multi-gate circuity.

Methodology in accordance with embodiments of the present disclosure includes forming a vertical gate to extend over a plurality of fins. Then, oxidizing each of a plurality of skirt regions formed at respective points of intersection of the gate with a plurality of fins to fill each of the plurality of the skirt regions. The oxidized gate skirts are formed to fill in the plurality of skirt regions, thereby taking on the shape of the skirt regions. Consequently, the area occupied by the oxidized gate skirts and the area of a low dielectric portion of the spacer makes up the effective area of the spacer.

Still other aspects, features, and technical effects will be readily apparent to those skilled in this art from the following detailed description, wherein preferred embodiments are shown and described, simply by way of illustration of the best mode contemplated. The disclosure is capable of other and different embodiments, and its several details are capable of modifications in various obvious respects. Accordingly, the drawings and description are to be regarded as illustrative in nature, and not as restrictive.

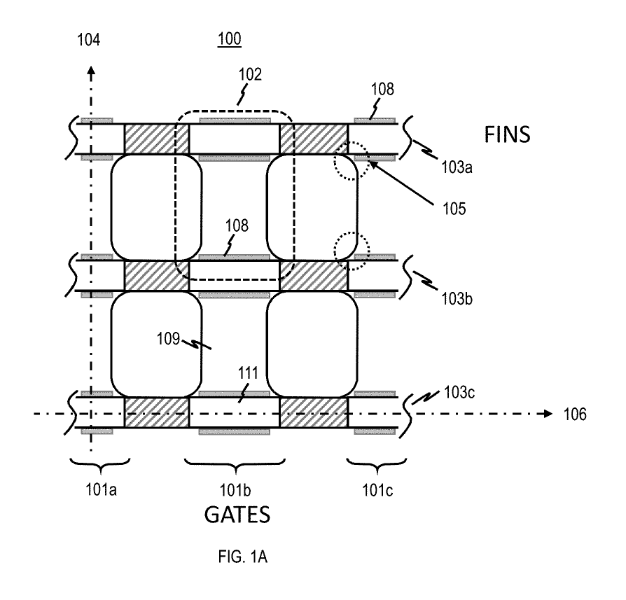

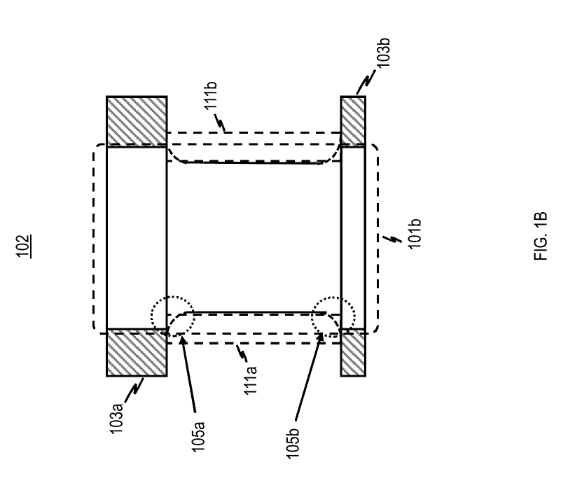

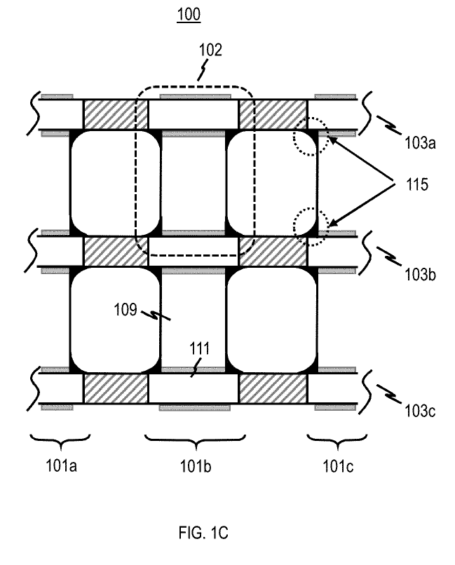

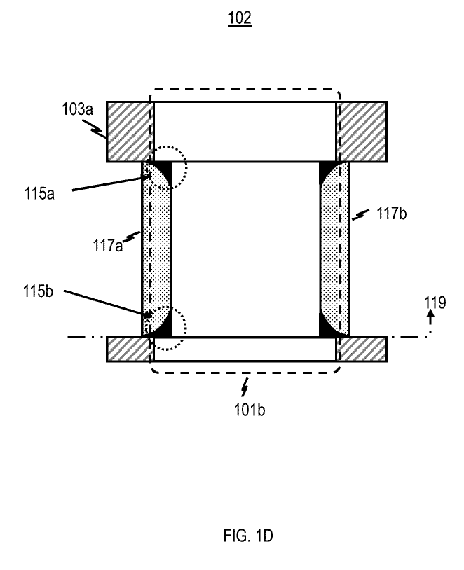

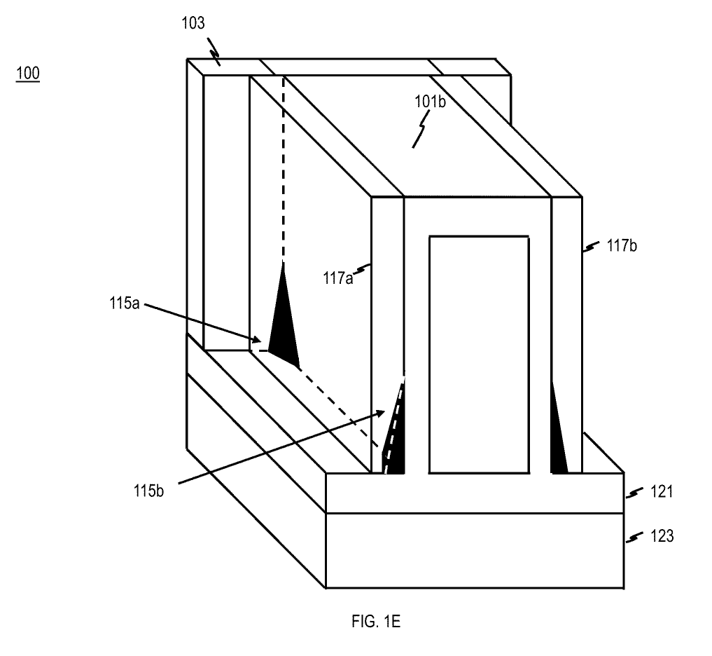

FIGS. 1A through 1B schematically illustrate top-down view of a FinFET having a plurality of skirt regions, in accordance with exemplary embodiments. Referring to FIG. 1A, a top-down view of a FinFET device 100 includes multiple fins 103a-103c (referred to herein collectively as fins 103) upon which multiple (metal) gates 101a-101c (referred to herein collectively as gates 101) are formed. The fins 103 may further include an ethylene glycol layer 108 for insulating the fins 103 from excessive heat deterioration during fabrication. For example, the ethylene glycol layer 108 may be of a suitable heat transfer coefficient for insulating the fins 103 during formation of the gates 101. Fins 103 are formed within a substrate (not shown for illustrative convenience) as structures that extend upward above a surface of the device 100. Hence, the fins provide a framework upon which multiple vertical gates 101 are eventually formed, i.e., as gate electrodes. In addition, an epitaxial layer (not shown for illustrative convenience) may be grown between or around the fins 103 for further development of the FinFET device 100.

In certain embodiments, the gates 101 are made of metal, such as a-Si, SiGe or epitaxial silicon. Alternatively, the gates 101 may be formed of polysilicon (polycrystalline silicon) as a polygate structure. For the purpose of illustration herein, the gates 101 may pertain to either form of gate electrode fabrication. Moreover, the gates 101 are formed to extend perpendicularly to the fins 103, resulting in a multi-gate device architecture for supporting multiple FinFETs. For example, gates 101 are shown as the non-shaded regions that extend across the device 100 surface in a direction 104 over multiple shaded fins 103a-103c extending a direction 106. As such, portions of each gate 101 body (e.g., portion 111 of gate 101b) extend directly over a respective fin 103c while other portions extend between respective fins 103b and 103c (e.g., portion 109 of gate 101b).

In certain embodiments, the substrate (not shown for illustrative convenience) from which the fins 103 are formed may be silicon (Si). The substrate is processed, by way of known lithography or etching techniques, to form the fins 103. A dielectric layer (not shown for illustrative convenience), provided as an insulator, may also be formed atop the substrate to provide a device 100 surface. In addition, the device 100 surface may be etched with lines/pattern markings for specifying placement of the plurality of gates 101 along the surface and over the fins 103. In the case of etching, the process may be performed, for example, as a dry etch, reactive ion etch (RIE), plasma etch, ion beam etch, laser ablation, etc.

In certain instances, one or more gate skirt regions 105 may be formed during the early stage etch process described above. By way of example, the gate skirt regions are curved areas or protrusions (e.g., ledges) formed at or near the surface of the substrate.

Referring to FIG. 1B, a zoomed in view of a portion 102 of the FinFET device 100 of FIG. 1A is shown for further depicting the gate skirt regions 105. In FIG. 1B, exemplary gate skirt regions 105a and 105b (referred to herein collectively as gate skirt regions 105) are shown to occur at a corner and/or point of intersection of fins 103a and 103b respectively with a gate 101b. Also shown are spacer regions 111a and 111b; open regions where low dielectric (low-k) spacers may ultimately be formed along each side of the gate 101b. The material used to form the low-k spacer may include a-Si, SiOCN or SiBCN or any other material suited for silicon based device fabrication. Under this instance, when the spacers are formed at corresponding regions 111a and 11b, the dielectric spacers eventually cover and/or encompass the metallicized gate skirt regions 105 depending on the dimensions of the gate skirt.

While shown as uniform in the exemplary embodiment, the dimensions of respective gate skirt regions 105a and 105b may vary in depth, size, shape, etc.; ultimately resulting in an additional length of the gate 101 contacting fins 103a and 103b respectively. The additional length of the gate due to a gate skirt may be given, for example, as:

Gate Skirt Length=Gate Metal Length+Dielectric Layer Length

In the case of small scale microprocessor design, the gate skirt length may be measured in nanometers. As noted previously, an increase in length (in nanometers) of the gate skirt corresponds to an increase in the effective capacitance across the gate 101b during operation of the FinFET device 100.

FIGS. 1C through 1D schematically illustrate top-down views of a FinFET having a plurality of oxidized skirts for filling in a plurality of skirt regions, in accordance with exemplary embodiments. Oxidized skirts 115 correspond to regions of the FinFET device 100 where the open gate skirt regions 105 of FIG. 1A are filled with an oxide layer. The oxide layer is formed, e.g., of SiO₂, SiON or TiO₂, over the skirt regions 105 by way of ALD or plasma enhanced ALD. Then, a plasma oxidation is performed to oxidize the skirt regions 105. For example, the FinFET device 100 is placed within a reaction chamber (not shown for illustrative convenience), and is exposed to precursors, e.g., (N,N-dimethylamino)trimethylsilane, (CH3)3 SiN(CH3)2, vinyltrimethoxysilane, trivinylmethoxysilane (CH2¼CH)3 SiOCH3), tetrakis (dimethylamino) silane Si(N(CH3)2)4, tris(dimethylamino)silane (TDMAS) SiH(N(CH3)2)3, CH2¼CHSKOCH3)3, Diisopropylaminosilane (DIPAS) with oxygen plasma as a reactant and bis(ethyl-methyl-amino)silane (BEMAS) with ozone as reactant, generated by delivering a power level, e.g., of 10 watts to 100 watts, to the reaction chamber at a flow rate, e.g., of 10 standard cubic centimeters per minute (SCCM) to 50 SCCM, for 60 seconds to 4 hours. The precursors may also be maintained at a pressure of 0 mTorr to 1 mTorr in the reaction chamber. This results in a thin oxide film being slowly deposited over the skirt region 105 to produce the oxidized gate skirts 115.

In an alternative embodiment, the oxidation process may be performed during a polycrystalline pulling procedure or other fabrication steps. In the case of the pulling process, polysilicon chunks or granules within the substrate and/or dielectric layer are embellished to optimize device performance. Per this approach, the oxide layer may be oxidized during the melting or pressurizing of the polysilicon. As such, the oxidized skirts 115 may be formed as an inherent part of the device fabrication process without requiring significant additional steps.

Referring to FIG. 1D, a zoomed in view of a portion 102 of the FinFET device 100 of FIG. 1C is shown for further depicting the oxidized gate skirts 115. In accordance with the exemplary embodiments, the spacers 117a and 117b extend along the sides of a gate 101b and adjacent to the oxidized gate skirts 115. As such, the opening formed by the gate skirts 105 of FIGS. 1A and 1B are replaced with the oxidized gate skirts 115 to become part of the effective area of the spacer. Resultantly, the gate length 101 is maintained by the spacer to design specification rather than having the additional gate skirt length.

FIG. 1E schematically illustrates a three-dimensional view of a cross-section of a FinFET having a plurality of oxidized skirts for filling in a plurality of skirt regions, in accordance with an exemplary embodiment. The cross section corresponds to a line 119 cut across the zoomed-in view of the portion 102 of the FinFET device 100 of FIG. 1D. In this example, the spacers 117a and 117b are shown as formed alongside a vertical gate 101b formed over an oxide layer 121, which further rests upon a substrate 123. Still further, the spacers 117a and 117b are formed to extend adjacent to the vertical gate 101b between fins 103 and over the oxidized skirts 115a and 115b, thus encompassing and/or merging the area of the oxidized skirts 115a and 115b as part of the effective area of the spacer 117a and 117b.

It is contemplated that the exemplary embodiments herein may pertain to any adjacent orientation of the oxidized skirts 115a and 115b and a respective spacer 117a and 117b. For example, the height or depth of the gate skirt may vary from that shown (e.g., may not occur near the surface of the oxide layer 121 and/or substrate 123), thus affecting the amount of oxidant applied or the amount of open space required for filling a gate skirt. The exemplary embodiments apply to any adjacent placement of the oxidized skirts and lower dielectric material wherein they become physically and/or functionally merged.

The exemplary processes described herein offer several advantages in the design and fabrication of FinFET devices. In one advantage, the gate skirt region of a device is oxidized during fabrication with no additional steps to improve the inherent AC power performance of the device. As another advantage, the gate metal length is maintained and the gate skirt region is effectively converted/merged with the low dielectric spacer. In another advantage, RX holes and defects occurring during the replacement metal gate process may be eliminated. Of note, the exemplary techniques presented herein may be integrated with any known complementary metal-oxide-semiconductor (CMOS) processing flows.

Devices formed in accordance with embodiments of the present disclosure enjoy utility in various industrial applications, e.g., microprocessors, smart-phones, mobile phones, cellular handsets, set-top boxes, DVD recorders and players, automotive navigation, printers and peripherals, networking and telecom equipment, gaming systems, and digital cameras. The present disclosure therefore enjoys industrial applicability in the manufacture of any of various types of highly integrated semiconductor devices. The present disclosure is particularly applicable in semiconductor devices such as FinFETs in advanced technology nodes.

In the preceding description, the present disclosure is described with reference to specifically exemplary embodiments thereof. It will, however, be evident that various modifications and changes may be made thereto without departing from the broader spirit and scope of the present disclosure, as set forth in the claims. The specification and drawings are, accordingly, to be regarded as illustrative and not as restrictive. It is understood that the present disclosure is capable of using various other combinations and embodiments and is capable of any changes or modifications within the scope of the inventive concept as expressed herein.

What is claimed is:

1. A method comprising:
forming a vertical gate to extend over a plurality of fins;
depositing a respective oxide layer over each of a plurality of skirt regions formed at respective points of intersection of the vertical gate with the plurality of fins; and
oxidizing each oxide layer to form a plurality of oxidized gate skirts.

2. The method according to claim 1, further comprising:
forming spacers along each side of the vertical gate and adjacent to the plurality of oxidized gate skirts,
wherein effective area of the spacers include respective area of the plurality of oxidized gate skirts.

3. The method according to claim 2, comprising forming the spacer of amorphous silicon (a-Si), silicon oxycarbonitride (SiOCN) or silicoboron carbonitride (SiBCN).

4. The method according to claim 1, comprising depositing the respective oxide layer by atomic layer deposition (ALD) or plasma enhanced ALD.

5. The method according to claim 1, wherein oxidizing each oxide layer further comprises:
applying precursors to the plurality of skirt regions for reacting with each respective oxide layer,
wherein the precursors include (N,N-dimethylamino)trimethylsilane, (CH3)3 SiN(CH3)2, vinyltrimethoxysilane, trivinylmethoxysilane (CH2¼CH)3 SiOCH3), tetrakis (dimethylamino) silane Si(N(CH3)2)4, tris(dimethylamino)silane (TDMAS) SiH(N(CH3)2)3, CH2¼CHSKOCH3)3, Diisopropylaminosilane (DIPAS) with oxygen plasma as a reactant and bis(ethyl-methyl-amino)silane (BEMAS) with ozone as reactant.

6. The method according to claim 5, wherein the reaction occurs within a reaction chamber at a temperature of room temperature to 600° C. and each respective oxide layer is exposed to the sequence of precursors for 20 seconds to 4 hours.

7. The method according to claim 6, wherein the reaction chamber is operated at a power level of 10 watts to 100 watts.

8. The method according to claim 6, wherein the reaction chamber is operated at an open valve pressure of 0 millitorr (mTorr) to 1 mTorr.

9. The method according to claim 1, comprising forming the oxide layer of silicon dioxide (SiO₂), silicon oxynitride (SiON) or titanium dioxide (TiO₂).

10. The method according to claim 1, comprising forming the vertical gate perpendicular to the plurality of fins, wherein the vertical gate comprises amorphous silicon (a-Si), silicon germanium (SiGe) or epitaxial silicon.

11. A device comprising:
a plurality of fins formed within a substrate;
a vertical gate formed to extend perpendicularly over the plurality of fins; and
a plurality of oxidized gate skirts formed to fill in respective skirt regions formed at a point of intersection of the vertical gate and the plurality of fins.

12. The device according to claim 11, further comprising:
spacers formed along each side of the vertical gate and adjacent to the plurality of oxidized gate skirts,
wherein effective area of the spacers include respective area of the plurality of oxidized gate skirts.

13. The device according to claim 12, wherein the spacers are formed of amorphous silicon (a-Si), silicon oxycarbonitride (SiOCN) or silicoboron carbonitride (SiBCN).

14. The device according to claim 11, further comprising:
a plurality of oxide layer deposited over each of the respective skirt regions.

15. The device according to claim 14, wherein the oxide layer is deposited by atomic layer deposition (ALD) or plasma enhanced ALD.

16. The device according to claim 11, wherein the oxide layer comprises silicon dioxide (SiO₂), silicon oxynitride (SiON) or titanium dioxide (TiO₂).

17. The device according to claim 11, wherein the vertical gate is perpendicular to the plurality of fins, and wherein the vertical gate comprises amorphous silicon (a-Si), silicon germanium (SiGe) or epitaxial silicon.

18. A device comprising:
a first and second oxidized portion of a spacer formed over a first and second skirt region of a gate; and
a low-dielectric portion of the spacer formed adjacent to the gate and the first and second oxidized portion of the spacer,
wherein the first and second skirt regions are formed at a respective point of intersection of the gate with a respective first and second fin.

19. The device according to claim 18, comprising forming the first and second oxidized portions of the spacer of silicon dioxide (SiO₂), silicon oxynitride (SiON) or titanium dioxide (TiO₂).

20. The device according to claim 18, comprising forming the low-dielectric portion of the spacer of amorphous silicon (a-Si), silicon oxycarbonitride (SiOCN) or silicoboron carbonitride (SiBCN).
